(19) United States
(12) Patent Application Publication
(10) Pub. No.: US 2013/0222017 A1
(43) Pub. Date: Aug. 29, 2013

(54) RESET DEVICE AND ELECTRONIC SYSTEM HAVING THE SAME

(71) Applicants: Chun-Yuan Su, Taoyuan County (TW); Ching-Ming Huang, Taipei City (TW)

(72) Inventors: Chun-Yuan Su, Taoyuan County (TW); Ching-Ming Huang, Taipei City (TW)

(73) Assignee: QUANTA COMPUTER INC., Taoyuan Shien (TW)

(21) Appl. No.: 13/489,259

(22) Filed: Jun. 5, 2012

(30) Foreign Application Priority Data
Feb. 29, 2012 (TW) 101106555

(51) Int. Cl. H03L 7/00

(52) U.S. Cl. 327/142

(57) ABSTRACT

An electronic system is provided. The electronic system comprises a power device and a reset device. The power device provides power to the electronic system. The reset device comprises a wireless signal generator, a wireless signal receiver and a control module. The wireless signal generator generates a wireless signal. The wireless signal receiver receives the wireless signal and generates a control signal in response. The control module is electrically connected to the wireless signal receiver to activate a reset mechanism of the control module or reset the power device upon reception of the control signal from the wireless signal receiver.

### RELATED APPLICATIONS

This application claims priority to Taiwan Application Serial Number 101106555, filed Feb. 29, 2012, which is herein incorporated by reference.

### BACKGROUND

1. Technical Field

The present disclosure relates to power-resetting technology. More particularly, the present disclosure relates to a reset device and an electronic system having the same.

2. Description of Related Art

Technology plays an integral part in the daily life for most people. Electronic systems such as desktops, laptops and handheld electronic devices (e.g., smartphones and tablet PCs) provide a convenient way of communication. With the increasing complexity of such electronic systems, a reset mechanism has become necessary to reset the electronic systems when they malfunction.

In general, an opening is formed on the enclosure of an electronic system to expose a reset button connected to the control module or power module inside the enclosure such that the user can reset the electronic system by pushing the reset button. The appearance of the enclosure of the electronic system is thus spoiled by the opening. Moreover, electrostatic discharge may penetrate the enclosure through the opening to damage the chips inside the enclosure.

Accordingly, a reset device and an electronic system having the same are needed to overcome the above issues.

### SUMMARY

An aspect of the present disclosure is to provide a reset device. The reset device comprises a wireless signal generator, a wireless signal receiver and a control module. The wireless signal generator generates a wireless signal. The wireless signal receiver receives the wireless signal and generates a control signal in response. The control module is electrically connected to the wireless signal receiver to activate a reset mechanism of the control module or reset a power device of the electronic system upon reception of the control signal from the wireless signal receiver.

Another aspect of the present disclosure is to provide an electronic system. The electronic system comprises a power device and a reset device. The power device provides power to the electronic system. The reset device comprises a wireless signal generator, a wireless signal receiver and a control module. The wireless signal generator generates a wireless signal. The wireless signal receiver receives the wireless signal and generates a control signal in response. The control module is electrically connected to the wireless signal receiver to activate a reset mechanism of the control module or reset the power device upon reception of the control signal from the wireless signal receiver.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawing as follows:

FIG. 1 is a block diagram of an electronic system in an embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and is the description to refer to the same or like parts.

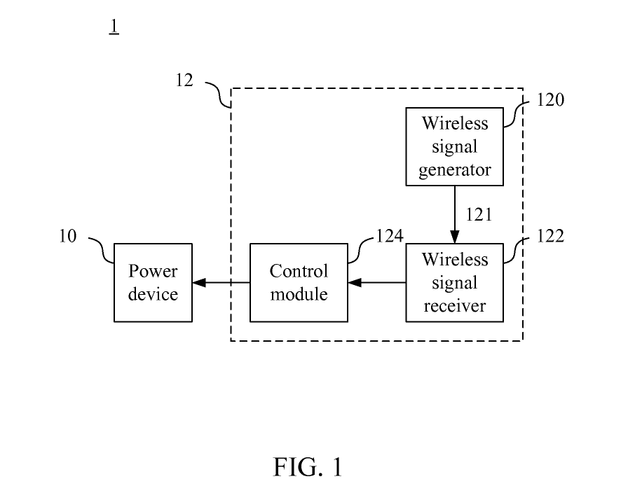

FIG. 1 is a block diagram of an electronic system 1 in an embodiment of the present disclosure. The electronic system 1 can be a desktop, a laptop or a handheld electronic device such as a smartphone or a tablet PC in different embodiments. The electronic system 1 comprises a power device 10 and a reset device 12.

The power device 10 provides power to each of the modules in the electronic system 1. The reset device 12 comprises a wireless signal generator 120, a wireless signal receiver 122 and a control module 124.

The wireless signal generator 120 generates a wireless signal 121, and the wireless signal receiver 122 receives the wireless signal 121 generated by the wireless signal generator 120. In an embodiment, the wireless signal generator 120 is a magnetic element and the wireless signal receiver 122 is a Hall sensor. In such an embodiment, the wireless signal 121 transmitted and received respectively by the wireless signal generator 120 and the wireless signal receiver 122 is the magnetic force generated by the magnetic element. In an embodiment, the strength of the magnetic force that can be detected by the Hall sensor can be modified as needed so that the Hall sensor can be triggered by magnetic materials having the strength of the magnetic force within a specific range only. For example, the wireless signal receiver 122 can be configured such that only a magnetic material producing a magnetic field which has a strength larger than 18 Gauss can trigger the wireless signal receiver 122.

In another embodiment, the wireless signal generator 120 is a supersonic wave generator and the wireless signal receiver 122 is a supersonic wave receiver. The range of the frequency of the supersonic wave that is generated by the wireless signal generator 120 and that can be detected by the wireless signal receiver 122 is about 2 MHz to 10 MHz. In different embodiments, the range of the frequency of the supersonic wave that can be detected by the wireless signal receiver 122 can be modified.

The control module 124 is electrically connected to the wireless signal receiver 122 to activate a reset mechanism of the control module 124 or reset the power device 10 upon reception of the wireless signal 121 from the wireless signal receiver 122. In an embodiment, the wireless signal receiver 122 further generates a control signal such that the control module 124 activates the reset mechanism of the control module 124 or reset the power device 10 upon reception of the control signal. In an embodiment, the control module 124 can be a chipset of the electronic system 1 when the electronic system 1 is a desktop computer or an X86 system of a laptop computer. In another embodiment, the control module 124 can be a power management chip of the electronic system 1 when the electronic system 1 is a handheld electronic device using an embedded system such as ARM as the primary architecture.

Consequently, the reset mechanism of the electronic system of the present disclosure can be accomplished rapidly by using the non-contact-type wireless signal generator and receiver of the reset device. Since it is not necessary to form any kind of opening for a reset button on the enclosure of the electronic system, any effect from or damage caused by electrostatic discharge can be avoided. In addition, the appearance of the enclosure of the electronic system is not spoiled by forming such an opening.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A reset device used in an electronic system, wherein the reset device comprises:
a wireless signal generator to generate a wireless signal;
a wireless signal receiver to receive the wireless signal and generate a control signal in response; and
a control module electrically connected to the wireless signal receiver to activate a reset mechanism of the control module or reset a power device of the electronic system upon reception of the control signal from the wireless signal receiver.

2. The reset device of claim 1, wherein the wireless signal generator is a magnetic element and the wireless signal receiver is a Hall sensor.

3. The reset device of claim 2, wherein the Hall sensor generates the control signal so as to cause the control module to activate the reset mechanism of the control module or reset the power device of the electronic system when a strength of a magnetic field of the magnetic element is larger than 18 Gauss.

4. The reset device of claim 1, wherein the wireless signal generator is an infrared signal generator and the wireless signal receiver is an infrared signal receiver.

5. The reset device of claim 1, wherein the wireless signal generator is a supersonic wave generator and the wireless signal receiver is a supersonic wave receiver.

6. The reset device of claim 1, wherein the control module is a power management chip of the electronic system.

7. The reset device of claim 1, wherein the control module is a chipset of the electronic system.

8. An electronic system comprising:
a power device to provide power to the electronic system; and
a reset device comprising:
a wireless signal generator to generate a wireless signal;
a wireless signal receiver to receive the wireless signal and generate a control signal in response; and
a control module electrically connected to the wireless signal receiver to activate a reset mechanism of the control module or reset the power device upon reception of the control signal from the wireless signal receiver.

9. The electronic system of claim 8, wherein the wireless signal generator is a magnetic element and the wireless signal receiver is a Hall sensor.

10. The electronic system of claim 9, wherein the Hall sensor generates the control signal so as to cause the control module to activate the reset mechanism of the control module or reset the power device of the electronic system when a strength of a magnetic field of the magnetic element is larger than 18 Gauss.

11. The electronic system of claim 8, wherein the wireless signal generator is an infrared signal generator and the wireless signal receiver is an infrared signal receiver.

12. The electronic system of claim 8, wherein the wireless signal generator is a supersonic wave generator and the wireless signal receiver is a supersonic wave receiver.

13. The electronic system of claim 8, wherein the control module is a power management chip of the electronic system.

14. The electronic system of claim 8, wherein the control module is a chipset of the electronic system.
